(19) United States
(12) Patent Application Publication
(10) Pub. No.: US 2026/0186967 A1
(43) Pub. Date: Jul. 2, 2026

(54) MECHANISMS OF DATA TRANSFER BETWEEN VOLATILE MEMORY AND NON-VOLATILE MEMORY IN A HYBRID COMPUTE DEVICE

(71) Applicant: Micron Technology, Inc., Boise, ID (US)

(72) Inventors: Jeffrey S. McNeil, Boise, ID (US); Eric N. Lee, San Jose, CA (US); Xiangyu Tang, San Jose, CA (US); Sundararajan Sankaranarayanan, Fremont, CA (US); Suresh Rajgopal, San Diego, CA (US); Akira Goda, Tokyo (JP)

(21) Appl. No.: 19/389,576

(22) Filed: Nov. 14, 2025

Related U.S. Application Data
(60) Provisional application No. 63/740,397, filed on Dec. 31, 2024.
(60) Provisional application No. 63/773,674, filed on Mar. 18, 2025.

(51) Int. Cl. G06F 12/0802

(52) U.S. Cl. CPC G06F 12/0802

(57) ABSTRACT

A compute device includes one or more volatile memory (VM) dies and a non-volatile memory (NVM) die, stacked with the VM dies. The NVM die includes a wide-bit input/output (I/O) interface. Through-silicon vias (TSVs) are formed through the VM dies and the NVM die and interconnected through microbumps. A logic die is stacked with the VM dies and the NVM die. The wide-bit I/O interface is configured to handle data transfers over the TSVs to and from the VM dies, through the logic die, at one of a data rate of the VM dies or at a reduced rate compared to the data rate of the VM dies.

### CLAIM OF PRIORITY

The present application claims the benefit under 35 U.S.C. § 119(e) of U.S. Provisional Ser. No. 63/740,397 filed Dec. 31, 2024, and Provisional Ser. No. 63/773,674 filed Mar. 18, 2025, which are incorporated by reference herein.

### TECHNICAL FIELD

Implementations of the disclosure relate generally to compute devices, and more specifically, relate to mechanisms of data transfer between volatile memory (VM) and non-volatile memory (NVM) in a hybrid compute device.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various implementations of the disclosure.

FIG. 1A is an example high-level component diagram of a hybrid VM/NVM compute device (or system) implemented according to some embodiments.

FIG. 1B is an example flow chart illustrating a method for dedicating a subset of the through-silicon vias (TSVs) to folding data between VM dies and NVM die of the compute device (or system) of FIG. 1A according to some embodiments.

FIG. 2 is an example high-level component diagram of a hybrid VM/NVM die stack of the hybrid VM/NVM compute device (or system) of FIG. 1A in which a stacked logic die facilitates VM-to-NVM data transfer over TSVs according to some embodiments.

FIG. 3 is an example high-level component diagram of NVM dies, within the VM/NVM die stack, each having a wide-bit input/output (I/O) interface coupled with various VM dies through a varying number of TSVs according to some embodiments.

FIG. 4 is a block diagram of an example NVM die having an NVM memory array wafer disposed on a complementary-metal-oxide semiconductor (CMOS) wafer, where a memory buffer is disposed on the CMOS wafer according to some embodiments.

FIG. 5 is a component block diagram of the hybrid VM/NVM compute device (or system) in which a memory buffer is disposed on the logic die according to some embodiments.

FIG. 6 illustrates an example computing system that includes a memory sub-system implemented in accordance with some implementations of the present disclosure.

FIG. 7 is a block diagram illustrating a system for performing AI model inference operations using memory devices and/or host systems implemented in accordance with aspects of the present disclosure.

FIG. 8 is a block diagram of an example computer system in which implementations of the present disclosure may operate.

### DETAILED DESCRIPTION

Aspects of the present disclosure are directed to employing, within a compute device or system, mechanisms of data transfer between VM and NVM memory in a hybrid compute device. A memory sub-system can include one or more storage devices, memory modules, and/or hybrid storage devices and memory modules. Examples of storage devices and memory modules are described below. In general, a host system can utilize a memory sub-system that includes one or more components, such as memory devices that store data. The host system can provide data to be stored at the memory sub-system and can request data to be retrieved from the memory sub-system.

A memory sub-system may utilize one or more memory devices, including any combination of the different types of non-volatile memory devices and/or volatile memory devices, to store the data provided by the host system. In some implementations, non-volatile memory devices may be provided by negative-and (NAND) type flash memory devices. A non-volatile memory device is a package of one or more dies. Each die (“logical unit”) may include one or more planes. For some types of non-volatile memory devices (e.g., NAND devices), each plane may include a set of physical blocks. Each block may in turn include a set of pages. Each page includes a set of memory cells. A memory cell is an electronic circuit that stores one or more bits of information.

A memory device may include multiple memory cells arranged in a two-dimensional grid. The memory cells can be formed onto a silicon wafer in an array of columns and rows. A memory cell includes a capacitor that holds an electric charge and a transistor that acts as a switch controlling access to the capacitor. Accordingly, the memory cell may be programmed (written to) by applying a certain voltage, which results in an electric charge being held by the capacitor. The memory cells are joined by wordlines, which are conducting lines electrically connected to the control gates of the memory cells, and bitlines, which are conducting lines electrically connected to the drain electrodes of the memory cells.

Depending on the cell type, each memory cell may store one or more bits of information and has various logic states that correlate to the number of bits being stored. The logic states may be represented by binary values, such as “0” and “1”, or combinations of such values. A memory cell may be programmed (written to) by applying a certain voltage to the memory cell, which results in an electric charge being held by the memory cell, thus allowing modulation of the voltage distributions produced by the memory cell. A set of memory cells referred to as a memory page may be programmed together in a single operation, e.g., by selecting consecutive bitlines.

Precisely controlling the amount of the electric charge stored by the memory cell allows establishing multiple logical levels, thus effectively allowing a single memory cell to store multiple bits of information. A read operation may be performed by comparing the measured threshold voltages (Vt) exhibited by the memory cell to one or more reference voltage levels in order to distinguish between two logical levels for single-level cell (SLCs) and between multiple logical levels for multi-level cells. Each logical level may be translated into a corresponding binary representation of the content of the memory cell.

Memory access operations (e.g., a read operation, a programming (write) operation, an erase operation, etc.) may be executed with respect to sets of the memory cells, e.g., in response to receiving memory access commands from the host. A memory access operation may specify the requested memory access operation (e.g., write, erase, read, etc.) and a logical address, which the memory sub-system would translate to a physical address identifying a set of memory cells (e.g., a block).

In some implementations, memory sub-systems can be used to store data used to train machine learning (ML) and artificial intelligence (AI) frameworks, as well as data on which the ML/AI framework can be executed. An ML/AI framework can include a model, which is a representation of a neural network designed to produce one or more outputs responsive to one or more inputs. In such frameworks, the amount of data used to train the ML models can be extremely large and a training process cycle can be executed multiple times (e.g., multiple “epochs”). For example, an ML framework used to classify an image as being a particular type of image (e.g., an image of a person, an animal, a type of animal, etc.) can utilize a large data set of stored images that are repeatedly processed in multiple epoch cycles to train the model. Similarly, data sets used for testing and/or inference stages of a ML/AI workflow can include very large amounts of data. For example, the inference stage utilizes the trained model, which is very large and requires significant storage, to make predictions or decisions on new input data. This process can include processing the input data, feeding it into the model, and post-processing the output of the model if necessary.

In order to process the large amounts of data, many host systems executing ML/AI frameworks include multiple processing units or compute devices (e.g., graphics processing units (GPUs) and/or central processing units (CPU)) which can process multiple threads/streams in parallel. During the inference phase, these processing units utilize relatively small chunks of data (e.g., tens or hundreds of bytes) from a significantly larger corpus of data (e.g., many gigabytes or terabytes) stored at a memory sub-system. For example, the inference phase may involve walking through multiple graph nodes in order to determine the value of a vertex element and identify its connections.

In some embodiments, the input data can be loaded from the memory sub-system to a local host memory co-located with the processing units executing the ML/AI framework. This host memory can be implemented using high bandwidth memory (HBM) devices that offer extremely high (i.e., fast) performance, but have relatively low storage capacities. In embodiments, multiple processing units or compute devices (GPUs and/or CPUs) can be connected to a shared memory pool, such that each processing unit can have its own local memory and can also access, over a high-speed interconnect, the memory that is local to other processing units. However, the local memory accesses would exhibit much lower latency as compared to the remote memory accesses.

Thus, memory capacity is one of the biggest challenges faced by enterprise deployment of ML/AI models. Various solutions involve increasing the number of dies stacked in HBM packages accessible by a processing unit or compute device (e.g., a GPU) and implementing various non-uniform memory access (NUMA) schemes in which a processing unit, in addition to its local memory, may also access a local memory of another processing unit. However, these and other solutions fail to adequately satisfy the growing memory capacity requirements while delivering the requisite memory access bandwidth and latency, not to mention containing the costs.

In some HBM packages, for example, several VM (e.g., HBM) dies are stacked with one or more NVM dies while using through-silicon vias (TSVs) that interconnect the stacked VM (or HBM) dies and the NVM dies. As is customary in hybrid memory packages such as this, whether stacked or not, the processing unit or compute device accesses the VM dies through different I/O interfaces and memory protocol than used with the NVM dies so as to maximize bandwidth and minimize latency through the faster-access memory provided by the VM dies compared to the NVM dies. The process of buffering data from the VM dies and folding that data into the NVM dies, therefore, is typically handled (or directed) by the processing unit, often by buffering the data in system memory.

Requiring data to be transferred outside of the stacked hybrid VM/NVM memory package so as to be properly written or folded back into flash arrays of the NVM die is time consuming, worsens latency and bandwidth, increases demand on processing threads of the processing unit (which would be better employed for ML/AI work), and increases costs with different I/O interfaces for the VM dies compared to the NVM dies. Data folding refers to the process of intelligently transferring or reorganizing data between volatile memory (e.g., dynamic random access memory or DRAM) and non-volatile memory (e.g., NAND flash, Optane, magnetoresistive RAM (MRAM), or other storage-class memory) to optimize performance, endurance, and power efficiency.

Aspects of the present disclosure address the above and other deficiencies by employing a wide-bit I/O interface on the NVM dies that are capable of receiving data directly from VM dies through a logic die that is also stacked with the hybrid VM/NVM dies. For example, typical NVM I/O interfaces employ 8-bit or 16-bit wide I/O channels over which to receive and transmit data. A wide-bit I/O interface is wider than this, being at least 32 bits wide but varying up to larger bits width-per-channel such as 128 bits or 1024 bits in width or wider (e.g., being ultra wide). Such a wide-bit I/O interface can be configured to handle data transfers over the TSVs to and from the one or more VM dies, through the logic die, at a data rate of the one or more VM dies or at a reduced rate compared to the data rate of the one or more VM dies. In this way, the wide-bit I/O interface can be configured to mimic, or nearly mimic, a double data rate (DDR) I/O interface of the VM dies.

Because increasing the width and the bandwidth of receiving data over such a wide-bit I/O interface could be faster than each NVM device can write or fold the data into the NVM arrays, embodiments of the present disclosure can include use of a memory buffer either on the logic die or on each NVM die. In varying embodiments, the memory buffer is composed of static RAM (SRAM) or DRAM. In some embodiments, the memory buffer is a first-in, first-out (FIFO) buffer, such that once data is buffered, the first data in is the first data to be written out to the NVM array (for folding) or the first data to be transmitted out the logic die to a requesting agent or host (for reading). Such a memory buffer makes it possible to hide the mismatch in latency and bandwidth between the NVM die and each VM die. For example, the memory buffer size can be designed based on a number of I/O interfaces of the one or more VM dies coupled to the wide-bit I/O interface through the logic die, the NVM array architecture of the NVM die, and NVM array memory access speeds.

Through employing any of the disclosed embodiments (e.g., employing a wide-bit I/O interface at NVM dies of the hybrid VM/NMV die package and/or a memory buffer disposed on the logic die of the hybrid memory package or on each NVM die) enables the disclosed embodiments to make communicating data directly between the VM dies and the NVM dies possible with a single protocol. While the logic die may help direct some of the data traffic, this may be primarily in how many TSVs to employ between each NVM die and any number of VM dies, and otherwise can act as a pass-through and/or buffering component. The benefits of these embodiments and implementations are to conserve time, e.g., reduces latency and increases bandwidth, decreases demand on processing threads of the processing unit or compute device (which would be better employed for ML/AI work), and decreases costs by employing compatible I/O interfaces across VM and NVM dies. These and other advantages will be apparent to those skilled in the art of hybrid VM/NVM memory sub-systems.

In some implementations, one or more hybrid compute devices implemented in accordance with one or more aspects of the present disclosure may be packaged into a specified form factor, e.g., a form factor utilized by non-volatile memory devices, a form factor utilized by storage devices (such as solid state drives (SSDs)), or the like. Using a standard memory form factor would facilitate seamless integration of the device into various computing systems, such as, e.g., Internet-of-Things (IoT) devices, wearable or portable computing devices, automotive computing devices, enterprise compute systems, or enterprise storage systems, etc.

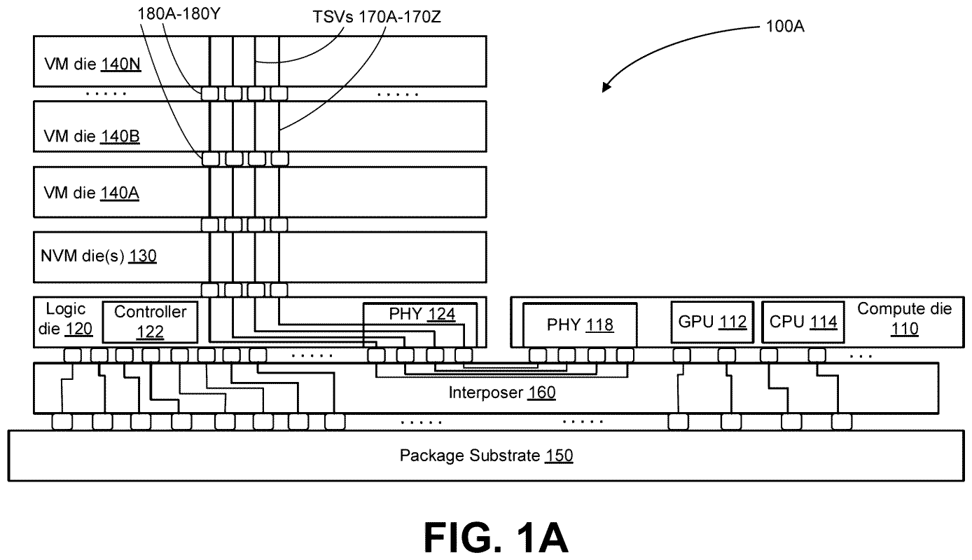

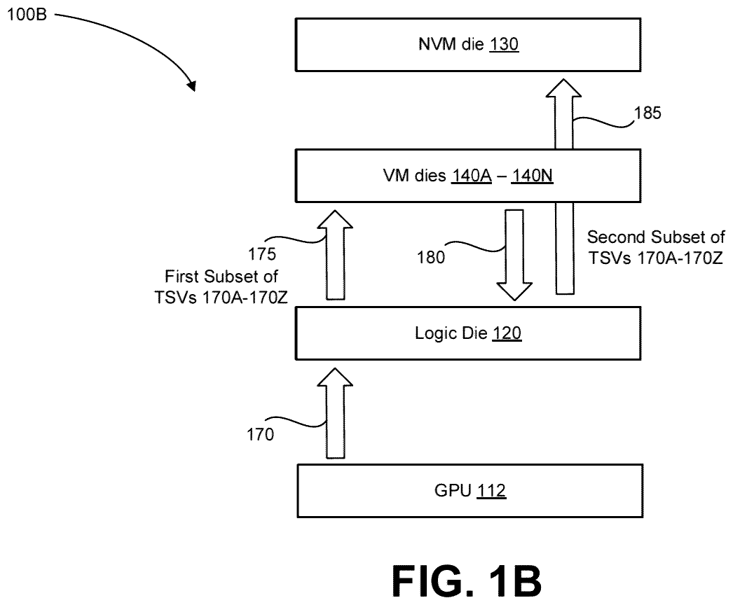

FIG. 1A is an example high-level component diagram of a hybrid VM/NVM compute device 100A (or system) implemented according to some embodiments. As schematically illustrated by FIG. 1A, the hybrid memory and compute device 100A may be implemented as an integrated circuit (IC) that includes a compute die 110, a logic die 120, one or more NVM dies 130, and one or more volatile memory (VM) dies 140A-140N, all the dies being disposed on a common package substrate 150.

Disposed on the compute die 110 are one or more processing units (e.g., one or more GPUs 112 and/or one or more CPUs 114) and their respective auxiliary circuitry, including local memory, input/output (I/O) interfaces, etc., which are omitted from FIG. 1A for clarity and conciseness. While a single compute die 110 is shown in FIG. 1A for clarity and conciseness, in various other implementations, device 100A may include two or more compute dies 110.

In some implementations, an NVM die 130 may be represented by a NAND die, which is representative of potentially several NVM dies 130. In some implementations, one or more NVM dies 130 may be single-level cell (SLC) NAND dies, which exhibit better endurance and lower access latency as compared, e.g., to multiple-level cell (MLC), triple-level cell (TLC), or quad-level cell (QLC) dies. In some implementations, a VM die 140 may be represented by an HBM DRAM die. While a single logic die 120 is shown in FIG. 1A for clarity and conciseness, in various other implementations, device 100A may include two or more logic dies 120.

The stacked VM dies 140, NVM dies 130, and the logic die 120 may be interconnected by through-silicon vias (TSVs) 170A-170Z and microbumps 180A-180Y. For example, the TSVs 170A-170Z may be formed through the VM dies 140A-140N as well as through the one or more NVM dies 130 while the microbumps 180A-180Y interconnect the TSVs 170A-170Z in between the VM/NVM dies. A TSV is a high-performance interconnect technique that utilizes a vertical electrical connection (via) that passes through a silicon wafer or die. “Microbumps” are small raised spheres which are made of a conductive material and connect a die with another die or a substrate, thus serving as conduits delivering electrical signals from one part of a chip to another, e.g., in these examples, through memory dies that are stacked together.

The components disposed on the compute die 110 may communicate with the components disposed on the logic die 120, components disposed on the NVM dies 130, and/or components disposed on the VM dies 140A-140N via respective physical interfaces (PHYs) 118, 124 interconnected by the interposer 160. An interposer is an electrical interface routing electrical signals between one socket or connection and another socket or connection. Thus, the memory access requests issued by the processing units residing on the compute die 110 may be transmitted via the interposer 160 to the logic die 120.

In embodiments, the controller 122 is disposed on the logic die 120 and configured to manage the NVM dies 130 and/or the VM dies 140. In some implementations, the controller 122 may implement a common logical address space for the VM dies 140A-140N and the NVM dies 130A-130K. Accordingly, the controller 122 may perform logical-to-physical (L2P) address translation based on the common logical address space. The controller 122 may also include media management logic (e.g., circuitry and/or firmware) for controlling the NVM dies and/or the VM dies 140 as will be explained in more detail.

In some implementations, no address translation (other than offsetting by a predefined value) may be required for the logical addresses that are below the upper limit of the user-addressable capacity of the VM dies 140A-140N. In other words, the logical addresses within the user-addressable capacity of the VM dies 140A-140N will directly (e.g., with an optional offset) reference respective memory locations on the VM dies 140A-140N, while the logical addresses exceeding the upper limit of the user-addressable capacity of the VM dies 140A-140N:
if LBA<=NVM Capacity then PA_{VM}=LBA+Offset
   else PA_{NVM}=L2P[LBA]
where LBA is the logical block address,
NVM Capacity is the user-addressable capacity of the VM dies 140A-140N,
PA_{VM} is the physical address of a transfer unit (TU) residing on the VM dies 140A-140N,

Offset is the optional offset to be applied to the logical addresses,

PA_{NVM} is the physical address of a TU residing on the NVM dies 130,

L2P[ . . . ] is the logical-to-physical (L2P) address translation table, and

L2P[LBA] is the physical address corresponding to the specified LBA.

In an illustrative example, the total user-addressable capacity of the VM dies 140A-140N may be 40 GB, while the total user-addressable capacity of the NVM dies 130 may be 128 GB. Thus, the memory access requests initiated by the compute die 110 with respect to TUs (such as memory pages, blocks, etc.) referenced by logical addresses below the upper limit of the user-addressable capacity of the VM dies 140A-140N may be satisfied directly via the physical interfaces 118 and 124 accessing the VM dies 140A-140N.

Conversely, memory access requests initiated by the compute die 110 with respect to TUs referenced by the logical addresses exceeding the upper limit of the user-addressable capacity of the VM dies 140A-140N may be sent to the controller 122, which may translate these logical addresses to corresponding physical addresses of TUs residing on the NVM dies 130. The address translation may be facilitated by a logical-to-physical (L2P) table, which may be indexed by the logical addresses so that each entry of the table would store a physical address corresponding to the logical address identifying the entry: PA_{NVM}=L2P[LBA].

In some embodiments, to avoid negatively impacting bandwidth and latency of the TSVs 170A-170Z and microbumps 180A-180Y, the controller 122 can write data to and read data from the one or more VM dies 140A-140N through a first subset of the TSVs 170A-170Z, e.g., all but one channel of the TSVs such as TSVs 180A-180W. The controller 122 can further fold the data from the one or more VM dies 140A-140N to the NVM die 130 through a second subset of the first plurality of TSVs that are fewer than the first subset and are dedicated to the folding of the data. For example, in some embodiments, the second subset of the TSVs include a single set of TSVs such as TSVs 180X-180Y. In this way, only a small portion of the TSVs are subjected to slower data rates, latency, and process of data folding.

FIG. 1B is an example flow chart illustrating a method 100B for dedicating a subset of the through-silicon vias (TSVs) to folding data between VM dies and NVM die of the compute device (or system) of FIG. 1A according to some embodiments. The method 100B may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In an illustrative example, the method 100B is performed by the controller 122 of FIG. 1A.

Although shown in a particular sequence or order, unless otherwise specified, the order of the operations may be modified. Thus, the illustrated implementations should be understood only as examples, and the illustrated operations may be performed in a different order, while some operations may be performed in parallel. Additionally, one or more operations may be omitted in some implementations. Thus, not all illustrated operations are required in every implementation, and other process flows are possible.

At operation 170, the processing logic receives data from the GPU 112, e.g., over one or more physical interfaces that interconnect the compute die 110 with the logic die 120.

At operation 175, the processing logic writes data over a first subset of the TSVs 170A-170Z to the one or more VM dies 140A-140N.

At operation 180, to fold the data previously written to the VM dies 140A-140N, the processing logic reads the data back out of the one or more VM dies 140A-140N over the second subset of the TSVs 170A-170Z. In some embodiments, the data will be read out of one of the VM dies 140A-140N.

At operation 185, to complete the folding of the data, the processing logic folds or writes the data from controller 122, over the second subset of the TSVs 170A-170Z, to the NVM die 130 which represents one or more NVM dies. In some embodiments, the second subset of the TSVs makes up a single channel while the first subset of the TSVs makes up the remainer (or majority) of the TSVs.

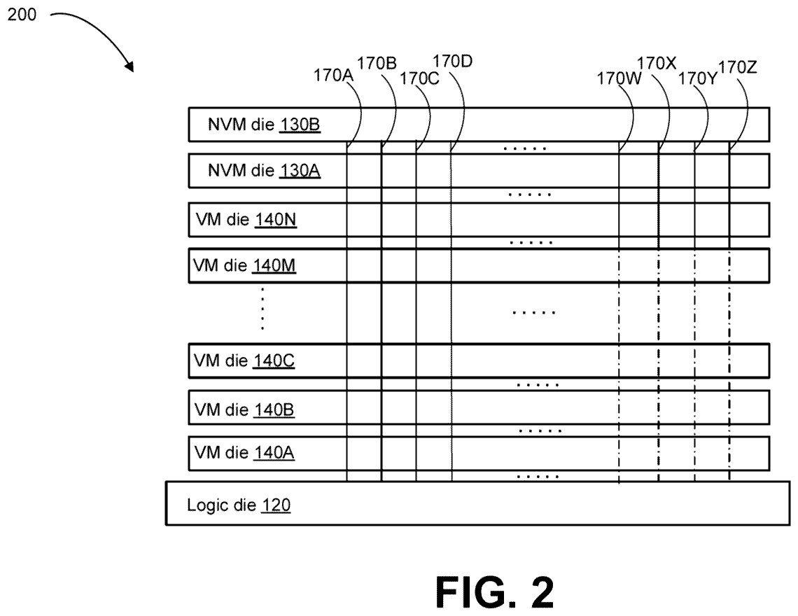

FIG. 2 is an example high-level component diagram of a hybrid VM/NVM die stack 200 of the hybrid VM/NVM compute device 100A (or system) of FIG. 1A in which a stacked logic die 120 facilitates VM-to-NVM data transfer over TSVs according to some embodiments. The hybrid VM/NVM die stack 200 can be understood as a more-detailed view of FIG. 1A, illustrating the VM dies 140A-140D and at least two NVM dies 130A and 130B. As discussed, the TSVs 170A-170Z are formed through the VM dies 140A-140N and the NVMs dies 130A-130B and interconnected through a plurality of microbumps (such as the microbumps 180A-180Y), which are not illustrated here for clarity. The microbumps also interconnect each TSV to the logic die 120. Although illustrated disposed on top of the stack of VM dies 140A-140N, the NVM dies 130A-130B can also be positioned at the bottom of the stack (as illustrated in FIG. 1A) with the VM dies 140A-140N disposed on top of the NVM dies 130A-130B.

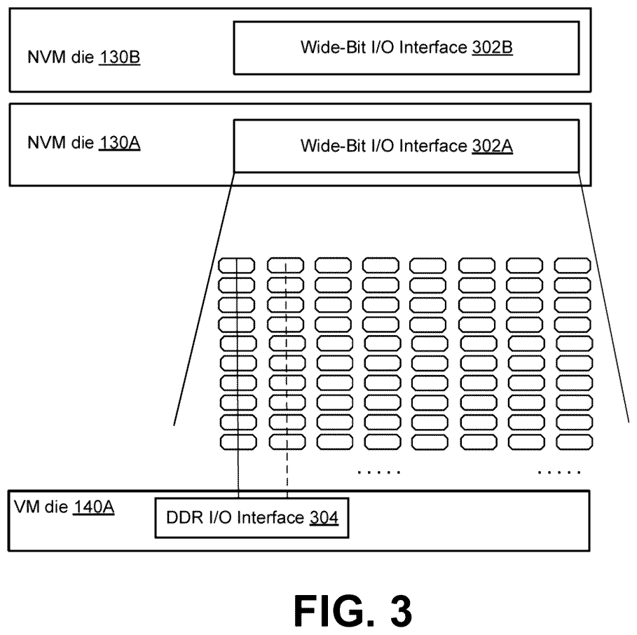

While each TSV (of the illustrated TSVs 170A-170L) is illustrated with a single line, it should be understood that, depending on the HBM architecture of any given package (of which FIG. 1A is an example), each of these lines could represent a large subset (such as hundreds or thousands) of TSVs for a given channel. For example, the number of TSVs for a given channel may depend on several factors, such as data width, signaling method, and required bandwidth. Thus, the dashed lines of a subset of TSVs 170W-170Z may be representative of a variable number of TSVs that can be activated and which are already interconnected between the VM dies 140A-140N, the NVM dies 130A-130B, and the logic die 120 (see FIG. 3).

In embodiments, bus width can be defined by a number of data lanes. A single data channel in memory interfaces (e.g., HBM, Wide I/O, 3D NAND) may include multiple data lines (DQ), control lines, and power/ground lines. High-performance memory like HBM2e and HBM3 may use a 1024-bit wide bus per memory stack, requiring thousands of TSVs.

In embodiments, a signaling method is either single-ended or differential. Single-ended signaling (e.g., DDR-like) may require only one TSV per signal line while differential signaling (e.g., PCIe-style, high-speed serializer-deserializer or SerDes) requires two TSVs per signal line (one for positive, one for negative). A memory interface also employs clock, command, and control signals, each requiring its own TSV(s). Additional TSVs for power and ground may be necessary to maintain signal integrity. Thus, the architecture and type of signal and communication interfaces may impact how many TSVs are employed.

FIG. 3 is an example high-level component diagram of the NVM dies 130A and 130B, within the VM/NVM die stack, each having a wide-bit input/output (I/O) interface coupled with the VM dies 140A-140N through a varying number of TSVs according to some embodiments. For example, a first NVM die 130A can include a first wide-bit I/O interface 302A and a second NVM die 130B can include a second wide-bit I/O interface 302B. As is expected, each VM die 140A-140N (the first of which is illustrated by way of example) includes a DDR I/O interface 304.

While employing a single TSV per VM die would be a straightforward design, for data transferred between the VM dies 140A-140N and the NVM dies 130A-130B, this may incur too many operational costs in not matching the bandwidth/latency of the VM dies at the NVM dies. Thus, in some embodiments, each wide-bit I/O interface 302A and 302B (at a NVM die) is configured to handle data transfers over the TSVs to and from the VM dies 140A-140N, through the logic die 120, at a data rate of the VM dies 140A-140N or at a reduced rate compared to the data rate of the VM dies 140A-140N. In this way, data can be transferred to and from the NVM dies from the VM dies at rate that more closely matches volatile memory data rates, enabling the ability to hide the latency and bandwidth mismatches between VM and NVM types of memory.

More specifically, in some embodiments, the TSVs are numbered according to a width of the wide-bit I/O interface 302A or 302B and includes a subset of TSVs coupled to the DDR I/O interface 304 of each respective VM die of the VM dies 140A-140N. In some embodiments, the logic die 120 customizes a number of TSVs in each subset of TSVs based on the DDR I/O interface 304 at each respective VM die (among other considerations discussed with reference to FIG. 2). For example, while NVM dies (such as 3D NAND flash) may employ around 100-500 TSVs per die, the control logic 120 can employ more of the existing TSVs 170A-170Z for any given data transfer to match the higher bandwidth capability of the wide-bit I/O interface 302A or 302B. In some implementations, therefore, one or more thousands of TSVs can be employed between each DDR I/O interface 304 of a respective VM die and a given wide-bit I/O interface of a NVM die in the hybrid VM/NVM die stack 200 of the hybrid VM/NVM compute device 100A.

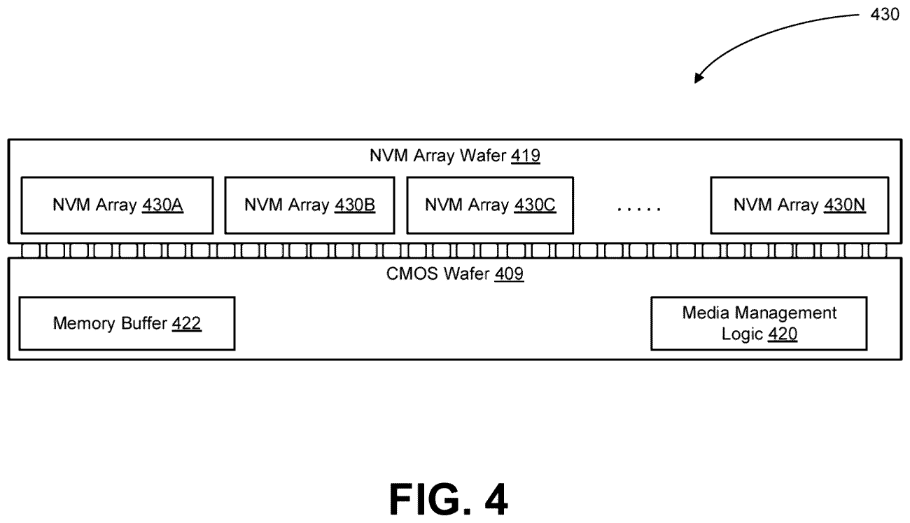

FIG. 4 is a block diagram of an example NVM die 430 having an NVM memory array wafer 419 disposed on a complementary-metal-oxide semiconductor (CMOS) wafer 409, and where a memory buffer 422 is disposed on the CMOS wafer 409 according to some embodiments. A plurality of NVM arrays 4230A-430N may be disposed on the NVM array wafer 419. In embodiments, the memory buffer 422 is composed of SRAM, DRAM, or other suitable RAM memory. In some embodiments, the memory buffer 422 is a FIFO buffer, enabling data associated with the write and read operations at the NVM dies 130A-130B to remain ordered similarly to issuance of those write and read operations (or commands).

The memory buffer 422 may be configured to buffer data associated with memory access operations conducted between the VM dies 140A-140N and the NVM dies 130A-130B. As can be appreciated, employing more TSVs over a wider interface at each NVM die can create a backlog of data on-board each NVM die (or at the logic die 120) due to the mismatch in data transfer speeds between VM and NVM media. Thus, as discussed, the inclusion of the memory buffer 422 at each NVM die 130A and 130B enables buffering data while waiting for the page buffers of the NVM dies to transfer data to or from the NVM arrays 430A-430N. Once a chunk of data is transferred (e.g., written to or read from) the NVM arrays 430A-430N, the memory buffer 422 is emptied and can be filled up again.

In at least some embodiments, the memory buffer is sized based on a number of I/O interfaces of the VM dies 140A-140N coupled to the wide-bit I/O interface 302A through the logic die 120, NVM array architecture of the NVM die 130A, and NVM array memory access speeds (exemplarily discussed with reference to the first NVM die 130). For example, for purposes of explanation and not limitation, assume 64-byte I/O lines and each I/O line loads 8 bytes at a time. To load or access 72 KB of data takes 960 ns (at 9200 MegaTransfers/second or MT/S), which is approximately one microsecond (1 μs). A read of an NVM array can take about 20 μs, which is approximately a 20× mismatch in data rate. In this particular embodiment, to hide latency of about 20 μs, the memory buffer 422 can be sized at approximately 185 MB per data channel of the proposed HBM architecture.

In various embodiments, media management logic 420 (e.g., circuitry and/or firmware) is also be included on the logic die 120 (e.g., in the controller 122 of FIG. 1A), which was previously discussed, or may be included in (e.g., disposed on) the CMOS wafer 409, and thus be included within a NVM die 430 of the hybrid VM/NVM die stack 200. In embodiments, the media management logic 420 performs low-density parity check (LDPC)-based data integrity checks on the data stored in the memory buffer 422, conducts wear-leveling of data written to the NVM die 130A, along with other such media management operations for the NVM die 130A. the LDPC-based data integrity checks may be adapted to with a single protocol that works across the VM dies 140A-140N and the NVM dies 130A-130B.

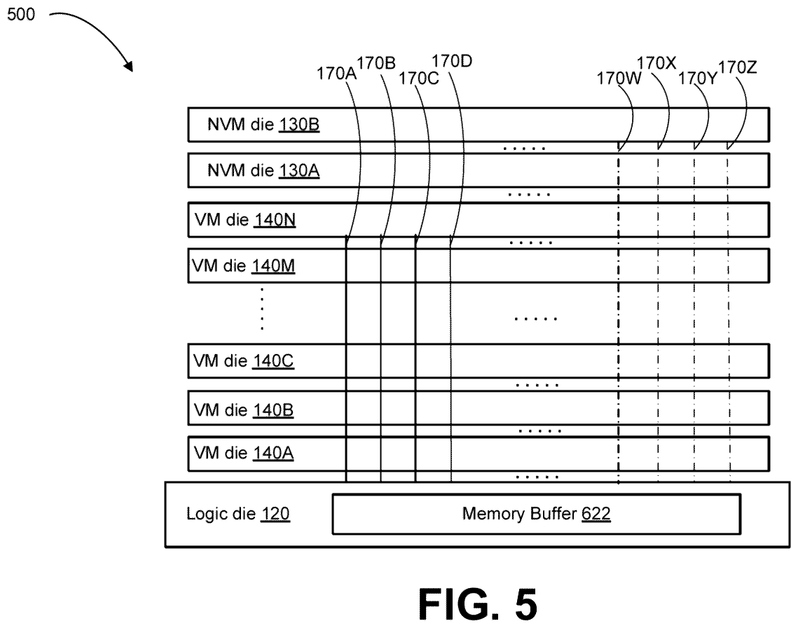

FIG. 5 is a component block diagram of the hybrid VM/NVM compute device 500 (or system) in which a memory buffer 622 is disposed on the logic die 120 according to some embodiments. While disposed on the logic die 120, the functionality and sizing of the memory buffer 622 can be expected to be similar to that of the memory buffer 422 disposed on the NVM dies 130A-130B, and thus the description of the memory buffer 422 with respect to FIG. 4 is equally applicable with reference to FIG. 5. Here, the data would be buffered on the logic die 120 for all NVM dies 130A-130B instead of being buffered on individual ones of the NVM dies 130A-130B. In some embodiments, some of the TSVs 170A-170D can be shortened to only pull data from the VM dies since the data would then be buffered at the memory buffer 622 before being written to (or folded at) the NVM dies 130A-130B over the subset of TSVs 170W-170Z.

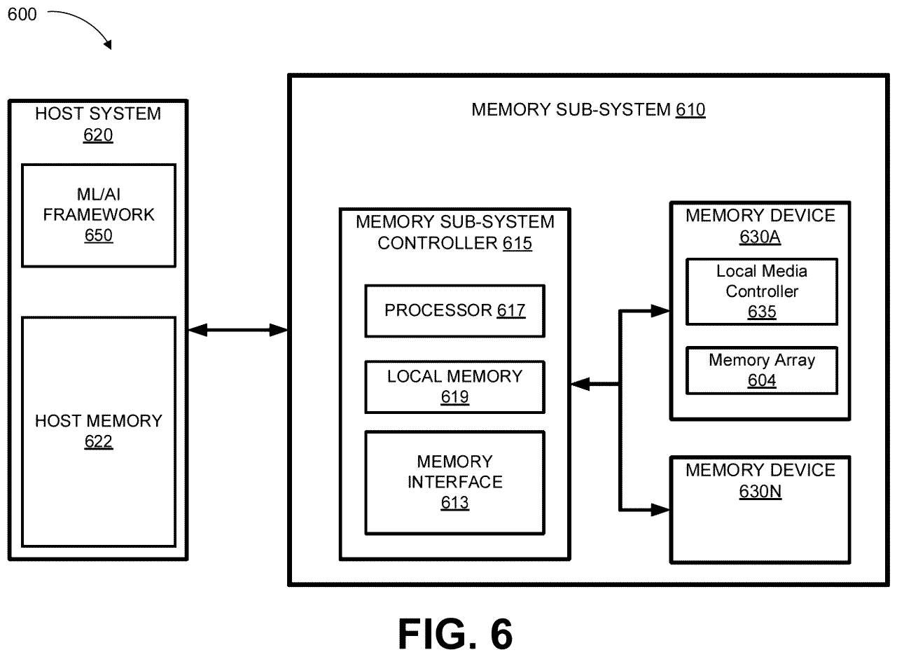

FIG. 6 illustrates a high-level component diagram of an example computing system 600 that includes a memory sub-system 610 in accordance with some implementations of the present disclosure. The memory sub-system 610 can include one or more memory devices 630A-630N, which may include one or more volatile memory devices, and/or one or more non-volatile memory devices. In an illustrative example, any combination of the one or more memory devices 630A-630N may be represented by any of the compute devices disclosed and described herein.

The memory sub-system 610 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 600 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 600 can include a host system 620 that is coupled to one or more memory sub-systems 630. In some implementations, the host system 620 is coupled to different types of memory sub-system 610. FIG. 6 illustrates one example of a host system 620 coupled to one memory sub-system 610. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 620 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 620 uses the memory sub-system 610, for example, to write data to the memory sub-system 610 and read data from the memory sub-system 610.

The host system 620 can be coupled to the memory sub-system 610 via a physical host interface. Examples of physical host interfaces include a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 620 and the memory sub-system 610. The host system 620 can further utilize an NVM Express (NVMe) interface to access the memory components (e.g., the one or more memory device(s) 630) when the memory sub-system 610 is coupled with the host system 620 by the physical host interface (e.g., PCIe or CXL bus). The physical host interface can provide an interface for passing control, address, data, and other signals between the memory sub-system 610 and the host system 620. FIG. 6 illustrates a memory sub-system 610 as an example. In general, the host system 620 can access multiple memory sub-systems via a same communication connection, multiple separate communication connections, and/or a combination of communication connections.

The memory devices 630A-630N can include any combination of the different types of non-volatile memory devices and/or volatile memory devices. In an illustrative example, one or more memory devices 630A-630N may be represented by any of the compute devices illustrated and described herein.

The volatile memory devices can be, e.g., random access memory (RAM), such as dynamic random access memory (DRAM) and synchronous dynamic random access memory (SDRAM). Some examples of non-volatile memory devices include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

A memory device 630A-630N can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some implementations, each of the memory devices 630A-630N can include one or more arrays of memory cells such as SLCs, MLCs, TLCs, QLCs, or any combination of such. In some implementations, a particular memory device can include an SLC portion, and an MLC portion, a TLC portion, or a QLC portion of memory cells. The memory cells of the memory devices 630A-630N can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory devices 630A-630N can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 615 can communicate with the memory device(s) 630A-630N to perform operations such as reading data, writing data, or erasing data at the memory devices 630A-630N and other such operations. The memory sub-system controller 615 can include hardware such as one or more integrated circuits and/or discrete components, a buffer memory, or a combination thereof. The hardware can include a digital circuitry with dedicated (i.e., hard-coded) logic to perform the operations described herein. The memory subsystem controller 615 can be a microcontroller, special purpose logic circuitry (e.g., a field programmable gate array (FPGA), an application specific integrated circuit (ASIC), etc.), or other suitable processor.

The memory sub-system controller 615 can include a processor 617 (e.g., a processing device) configured to execute instructions stored in a local memory 619. In the illustrated example, the local memory 619 of the memory sub-system controller 615 includes an embedded memory configured to store instructions for performing various processes, operations, logic flows, and routines that control operation of the memory sub-system 610, including handling communications between the memory sub-system 610 and the host system 620.

In some implementations, the local memory 619 can include memory registers storing memory pointers, fetched data, etc. The local memory 619 can also include read-only memory (ROM) for storing micro-code. While the example memory sub-system 610 in FIG. 6 has been illustrated as including the memory sub-system controller 615, in another implementation of the present disclosure, a memory sub-system 610 does not include a memory sub-system controller 615, and can instead rely upon external control (e.g., provided by an external host, or by a processor or controller separate from the memory sub-system).

In general, the memory sub-system controller 615 can receive commands or operations from the host system 620 and can convert the commands or operations into instructions or appropriate commands to achieve the desired access to the memory device(s) 630. The memory sub-system controller 615 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory device(s) 630A-630N. The memory sub-system controller 615 can further include host interface circuitry to communicate with the host system 620 via the physical host interface. The host interface circuitry can convert the commands received from the host system into command instructions to access the memory device(s) 630A-630N as well as convert responses associated with the memory device(s) 630A-630N into information for the host system 620.

The memory sub-system 610 can also include additional circuitry or components that are not illustrated. In some implementations, the memory sub-system 610 can include a cache or buffer (e.g., DRAM) and address circuitry (e.g., a row decoder and a column decoder) that can receive an address from the memory sub-system controller 615 and decode the address to access the memory device(s) 630.

In some implementations, the memory device(s) 630A-630N include local media controllers 635 that operate in conjunction with memory sub-system controller 615 to execute operations on one or more memory cells of the memory device(s) 630A-630N. An external controller (e.g., memory sub-system controller 615) can externally manage the memory device 630A-630N (e.g., perform media management operations on the memory device(s) 630A-630N). In some implementations, a memory device 630A-630N is a managed memory device, which is a raw memory device (e.g., memory array 604) having control logic (e.g., local controller 635) for media management within the same memory device package. An example of a managed memory device is a managed NAND (MNAND) device. Memory device(s) 630A-630N, for example, can each represent a single die having some control logic (e.g., local media controller 635) embodied thereon. In some implementations, the local media controller 635 may be represented by the controller 122 of FIG. 1A or media management logic 420 discussed herein.

In some implementations, the memory sub-system 610 includes a memory interface 613 that is responsible for handling interactions of memory sub-system controller 615 with the memory devices of memory sub-system 610, such as memory devices 630A-630N. For example, the memory interface 613 can send or transmit memory access commands corresponding to requests received from host system 620 to memory devices 630A-630N, such as program commands, read commands, or other commands. In addition, the memory interface 613 can receive data from devices 630A-630N, such as data retrieved in response to a read command or a confirmation that a program command was successfully performed. In some implementations, the memory sub-system controller 615 includes at least a portion of the memory interface 613. For example, the memory sub-system controller 615 can include a processor 617 (processing device) configured to execute instructions stored in local memory 619 for performing the operations described herein.

In some implementations, the host system 620 implements an ML/AI framework 650. ML/AI framework 650 can include one or more ML models, a processing engine, and a training engine, among other components, which can be used to perform any automated task (e.g., classify or categorize documents or images). In order to train the one or more ML models, ML/AI framework 650 can issue requests to read the training data, which may be stored on one or more memory devices 630A-630N, and process the training data accordingly. In some implementations, ML/AI framework 650 is executed by multiple processing units (e.g., GPUs and/or CPUs) which can process many threads/streams in parallel.

In some implementations, host system 620 could include hundreds of parallel processing threads that can request and process different subsets of the training data concurrently. In some implementations, at least some of the processing tasks of the ML/AI framework 650 are performed by the compute die 110 of the compute device 100A (FIG. 1A) or by the processing units 512, 514 residing on any of the hybrid memory devices described herein. In embodiments, one or more of the compute device or the hybrid memory devices are employed by the memory sub-system as memory devices 630A-630N.

Once a certain amount of training is complete, ML/AI framework 650 can enter an inference phase to analyze different input data. The input data can similarly be stored on memory devices 630A-630N of the same or a different memory sub-system 610. In some implementations, ML/AI framework 650 can issue requests to read the input data from memory sub-system 610 and store a copy of the input data in the host memory 622.

In some implementations, the host system 620 utilizes a set of queues to track the memory access commands issued to the memory sub-system 610 (e.g., requests to read data for ML/AI framework 650). For example, the host system 620 can include a number of submission queues, storing submission queue entries representing the memory access commands issued to the memory sub-system 610, and a number of completion queues, storing completion queue entries received from the memory sub-system 610 to indicate that the corresponding memory access commands have been executed. In some implementations, the host system 620 can maintain these queues in the host memory 622.

The host memory 622 may include one or more DRAM devices, HBM devices, and/or other types of memory devices. In some implementations, the host memory 622 includes the compute device 100A of FIG. 1A.

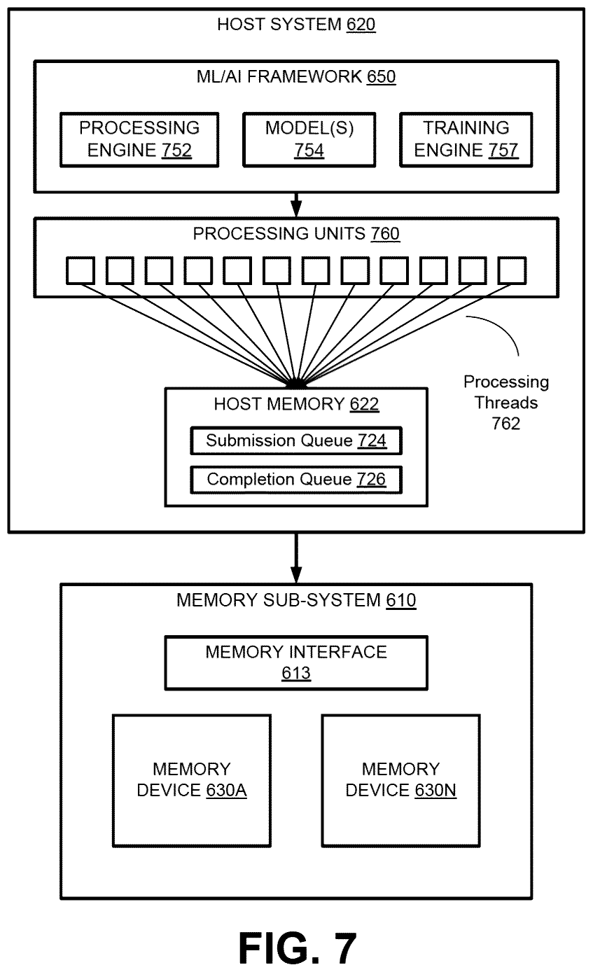

FIG. 7 is a block diagram illustrating a system for performing AI model inference operations using memory devices and/or host systems implemented in accordance with aspects of the present disclosure. As illustrated, host system 620 includes ML/AI framework 650 which can be executed by a number of processing threads 762. Host system 620 further includes host memory 622, including submission queues 724 and completion queues 746. In some implementations, ML/AI framework 650 includes a processing engine 752, one or more machine learning models 754, and a training engine 756, among other components, which can be used to perform any automated task (e.g., classify or categorize documents or images). Depending on the implementation one or more components that make up ML/AI framework 650 can be distributed across multiple different computing devices (e.g., host computers, servers, etc.). In some implementations, processing engine 752 may use a set of trained machine learning models 754 that are trained and used to perform any number of automated operations. The processing engine 752 may also preprocess any received input data prior to using the data for training of the set of machine learning models 754 and/or applying the set of trained machine learning models 754 to the input data. Based on the output of the set of trained machine learning models 754, the processing engine 752 may obtain, for example, a classification and/or category of the input data, as well an assessment of the classification.

In some implementations, at least some of the processing tasks of the ML/AI framework 650 are performed by the compute die 110 (e.g., by the GPU 112 and/or CPU 114) residing on the compute device 110A of FIG. 1A. In embodiments, the compute device 100A is employed by the memory sub-system 610 as memory devices 630A-630N.

The set of machine learning models 774 may refer to model artifacts that are created by the training engine 756 using training data that includes training inputs and corresponding target outputs (i.e., correct answers for respective training inputs). During training, patterns in the training data that map the training input to the target output (i.e., the answer to be predicted) can be found, and are subsequently used by the machine learning models 754 for future predictions. Depending on the implementation, the set of machine learning models 754 may be composed of, for example, a single level of linear or non-linear operations (e.g., a support vector machine [SVM]) or may be a deep network, (i.e., a machine learning model that is composed of multiple levels of non-linear operations). Examples of deep networks are neural networks including convolutional neural networks, recurrent neural networks with one or more hidden layers, and fully connected neural networks.

Thus, in order to train and utilize the one or more machine learning models 754, ML/AI framework 650 can issue requests to read training data and input data, which may be stored on memory device 630A-630N of memory sub-system 610, and process the data accordingly. In some implementations, these memory access requests are sent by the parallel processing threads 762 being executed by respective processing units 760. The processing units 760 can include a number of general-purpose processing devices such as microprocessors, central processing units (CPUs), or the like, or more specialized processing devices, such as graphics processing units (GPUs), which may be optimized for performing high-speed sequential processing operations. Thus, at least some of the processing units 760 may be the GPU 112, CPU 114, or other processing units on the compute die 110 of FIG. 1A.

Depending on the implementation there can be any number of processing units 760 (e.g., tens or hundreds), each executing a respective one or more of the processing threads 762. Each processing thread 762 represents a series of sequential operations directed to memory subsystem 610 (e.g., read requests for separate segments of an element of training or input data stored at memory sub-system 610). Due to the large relative size of the training data or input data, each element may be broken up into separate segments of a smaller fixed size and stored at sequential memory addresses in memory sub-system 610. Thus, in order to read the entire element of data, a sequence of multiple read requests can be issued to obtain all of the separate segments. Each processing thread 762 can include a series of read requests to read the segments of a different element of data from memory sub-system 610. Upon the read requests from each processing thread 762 being generated, the requests can be stored as entries in one of submission queues 724, from which they can be issued to memory sub-system 610. Received responses to the requests from memory sub-system 610 can be stored as entries in one of completion queues 746, retrieved by processing threads 762 and provided to ML/AI framework 650 for execution in either a training phase or an inference phase.

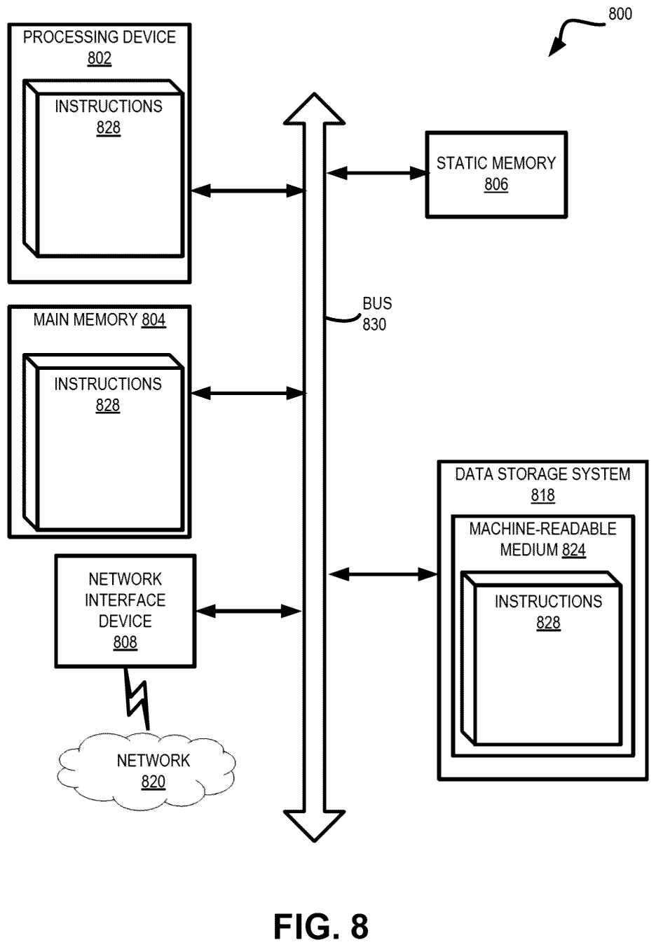

FIG. 8 illustrates an example machine of a computer system 800 within which a set of instructions, for causing the machine to perform any one or more of the methodologies discussed herein, can be executed. In some implementations, the computer system 800 can correspond to a host system (e.g., the host system 620 of FIG. 6) that includes, is coupled to, or utilizes a memory sub-system (e.g., the memory sub-system 610 of FIG. 6) or can be used to perform the operations of a controller (e.g., to execute an operating system to perform operations corresponding to the memory interface 613 or memory sub-system controller 615 of FIG. 6). In alternative implementations, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 828 for performing the operations and steps discussed herein. The computer system 800 can further include a network interface device 808 to communicate over the network 820.

The data storage system 818 can include a machine-readable storage medium 824 (also known as non-transitory computer-readable storage medium) on which is stored one or more sets of instructions 828 (executable instructions) or software embodying any one or more of the methodologies or functions described herein. The instructions 828 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory sub-system 610 of FIG. 6. In some implementations, the data storage system 818 may include the compute device 100A disclosed herein in FIG. 1A.

In some implementations, the instructions 828 include instructions to implement functionality corresponding to the memory interface 613 of FIG. 6). While the machine-readable storage medium 824 is shown in an example implementation to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some implementations, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, implementations of the disclosure have been described with reference to specific example implementations thereof. It will be evident that various modifications can be made thereto without departing from the broader spirit and scope of implementations of the disclosure as set forth in the following claims. The specification and drawings are, accordingly, to be regarded in an illustrative sense rather than a restrictive sense.

What is claimed is:

1. A compute device comprising:
one or more volatile memory (VM) dies
a non-volatile memory (NVM) die, stacked with the one or more VM dies, and comprising a wide-bit input/output (I/O) interface;
a plurality of through-silicon vias (TSVs), formed through the one or more VM dies and the NVM die, and interconnected through a plurality of microbumps; and
a logic die stacked with the one or more VM dies and the NVM die,
wherein the wide-bit I/O interface is configured to handle data transfers over the plurality of TSVs to and from the one or more VM dies, through the logic die, at one of a data rate of the one or more VM dies or at a reduced rate compared to the data rate of the one or more VM dies.

2. The compute device of claim 1, wherein the plurality of TSVs are numbered according to a width of the wide-bit I/O interface and comprises a subset of TSVs coupled to a double data rate (DDR) I/O interface of each respective VM die of the one or more VM dies, and wherein the logic die is to customize a number of TSVs in each subset of TSVs based on the DDR I/O interface at each respective VM die.

3. The compute device of claim 1, further comprising a memory buffer disposed on the logic die and to buffer data associated with memory access operations conducted between the one or more VM dies and the NVM die.

4. The compute device of claim 3, wherein the memory buffer is sized based on:
a number of I/O interfaces of the one or more VM dies coupled to the wide-bit I/O interface through the logic die;
NVM array architecture of the NVM die; and
NVM array memory access speeds.

5. The compute device of claim 3, wherein the memory buffer comprises at least one of static random access memory (SRAM) or dynamic random access memory (DRAM) and is a first-in, first-out (FIFO) buffer.

6. The compute device of claim 3, wherein the logic die comprises media management logic configured to:
perform low-density parity check (LDPC)-based data integrity checks on the data stored in the memory buffer; and
conduct wear-leveling of data written to the NVM die.

7. The compute device of claim 1, further comprising a memory buffer disposed on a complementary-metal-oxide semiconductor (CMOS) wafer of the NVM die and to buffer data associated with memory access operations conducted between the one or more VM dies and negative-AND (NAND) arrays of the NVM die.

8. The compute device of claim 7, wherein the memory buffer is sized based on:
a number of I/O interfaces of the one or more VM dies coupled to the wide-bit I/O interface through the logic die;
NVM array architecture of the NVM die; and
NVM array memory access speeds.

9. The compute device of claim 7, wherein the memory buffer comprises at least one of static random access memory (SRAM) or dynamic random access memory (DRAM) and is a first-in, first-out (FIFO) buffer.

10. The compute device of claim 7, wherein the CMOS wafer comprises media management logic configured to:
perform low-density parity check (LDPC)-based data integrity checks on the data stored in the memory buffer; and
conduct wear-leveling of data written to the NVM die.

11. A compute system comprising:
one or more volatile memory (VM) dies;
one or more non-volatile memory (NVM) dies, stacked with the one or more VM dies, and each comprising a wide-bit input/output (I/O) interface;
a plurality of through-silicon vias (TSVs), formed through the one or more VM dies and the one or more NVM dies, and interconnected through a plurality of microbumps;
a logic die stacked with the one or more VM dies and NVM dies; and
a memory buffer disposed on one of the logic die or the one or more NVM dies, the memory buffer to buffer data associated with memory access operations conducted between the one or more VM dies and the one or more NVM dies through the plurality of TSVs.

12. The compute system of claim 11, wherein each wide-bit I/O interface is configured to handle data transfers over the plurality of TSVs to and from the one or more VM dies, through the logic die, at a data rate of the one or more VM dies or at a reduced rate compared to the data rate of the one or more VM dies.

13. The compute system of claim 12, wherein the plurality of TSVs are numbered according to a width of each wide-bit I/O interface and comprises a subset of TSVs coupled to a double data rate (DDR) I/O interface of each respective VM die of the one or more VM dies, and wherein the logic die is to customize a number of TSVs in each subset of TSVs based on the DDR I/O interface at each respective VM die.

14. The compute system of claim 11, wherein the memory buffer is sized based on:
a number of I/O interfaces of the one or more VM dies coupled to the wide-bit I/O interface through the logic die;
NVM array architecture of the one or more NVM dies; and
NVM array memory access speeds.

15. The compute system of claim 11, wherein the memory buffer comprises at least one of static random access memory (SRAM) or dynamic random access memory (DRAM) and is a first-in, first-out (FIFO) buffer.

16. The compute system of claim 11, wherein the logic die comprises media management logic configured to:
perform low-density parity check (LDPC)-based data integrity checks on the data stored in the memory buffer; and
conduct wear-leveling of data written to the one or more NVM dies.

17. The compute system of claim 11, wherein the memory buffer is disposed on a complementary-metal-oxide semiconductor (CMOS) wafer of each NVM die of the one or more NVM dies.

18. The compute system of claim 17, wherein the CMOS wafer comprises media management logic configured to:
perform low-density parity check (LDPC)-based data integrity checks on the data stored in the memory buffer; and
conduct wear-leveling of data written to the one or more NVM dies.

19. A compute device comprising:
one or more volatile memory (VM) dies;
one or more non-volatile memory (NVM) dies, stacked with the one or more VM dies, and each comprising a wide-bit input/output (I/O) interface;
a plurality of through-silicon vias (TSVs), formed through the one or more VM dies and the one or more NVM dies, and interconnected through a plurality of microbumps; and
a logic die stacked with the one or more VM dies and NVM die; and
wherein each wide-bit I/O interface is configured to handle data transfers over the plurality of TSVs to and from the one or more VM dies, through the logic die, at a data rate of the one or more VM dies or at a reduced rate compared to the data rate of the one or more VM dies.

20. The compute device of claim 19, wherein the plurality of TSVs are numbered according to a width of each wide-bit I/O interface and comprises a subset of TSVs coupled to a double data rate (DDR) I/O interface of each respective VM die of the one or more VM dies, and wherein the logic die is to customize a number of TSVs in each subset of TSVs based on the DDR I/O interface at each respective VM die.
